(19) United States
(12) Patent Application Publication
(10) Pub. No.: US 2024/0117084 A1
(43) Pub. Date: Apr. 11, 2024

(54) CURABLE COMPOSITION

(71) Applicant: DONGJIN SEMICHEM CO., LTD., Incheon (KR)

(72) Inventors: Young Jin KWON, Hwaseong-si (KR); Seong Chan SON, Hwaseong-si (KR); Jin Wuk KIM, Hwaseong-si (KR); Dong Min KIM, Hwaseong-si (KR); Ja Hun BYEON, Hwaseong-si (KR)

(21) Appl. No.: 18/464,588

(22) Filed: Sep. 11, 2023

(30) Foreign Application Priority Data
Sep. 15, 2022 (KR) 10-2022-0116117
Sep. 8, 2023 (KR) 10-2023-0119416

(51) Int. Cl. C08F 122/10; C08F 120/30; C08F 122/20; C09D 133/14; C09D 135/02; H10K 59/80

(52) U.S. Cl. CPC C08F 122/1006; C08F 120/30; C08F 122/20; C09D 133/14; C09D 135/02; H10K 59/873

(57) ABSTRACT

A curable composition is provided. The curable composition can eliminate or minimize the generation of bubbles inside the cured product after the initiation reaction of the curable monomer, prevent expansion of a material when used to encapsulate a device, and provide a uniform cured product to solve the problem of separation between the upper and lower substrates bonded together, thereby improving device encapsulation performance.

### CROSS-REFERENCE TO RELATED APPLICATION(S)

This application claims priority from Korean Patent Application Nos. 10-2023-0119416 filed Sep. 8, 2023 and 10-2022-0116117 filed Sep. 15, 2022. The aforementioned applications are incorporated herein by reference in their entireties.

### TECHNICAL FIELD

The present invention relates to a curable composition for encapsulating devices.

### RELATED ART

An organic light emitting device (OLED) is a self-light emitting device and uses an organic material as a light emitting layer. Thus, the OLED is very vulnerable to oxygen and moisture. When oxygen or moisture permeates into the device, the organic light emitting layer is oxidized to lower brightness and drastically shorten its lifetime. Therefore, an encapsulation technology that protects from oxygen or moisture flowing in from the outside is being used.

The encapsulation technology consists of an inner filler and an outer sealant between a lower TFT substrate and an upper substrate, among which the filler is used to fill the space between the upper and lower substrates.

Since the filler transmits light from the light emitting region, transparency is important, and a moisture absorption capability can be imparted to delay the path of moisture penetrating from the sealant.

In recent years, low current driving is required to increase the lifetime and decrease power consumption of the organic light emitting device (OLED), and also in order to achieve high brightness at low current, it is necessary to increase the refractive index of the filler layer to thereby improve the light extraction efficiency.

Conventional fillers for encapsulation materials have been developed mainly based on thermosetting type epoxy resins.

Since the properties of existing materials fill the space between the upper and lower substrates, light passes through the filler in the light emitting region, and therefore, the optical properties of the filler are important.

Further, in the organic light emitting device, light is emitted from the light emitting layer to the outside, and light loss increases due to a difference in refractive index between the layers. Therefore, in recent years, in order to improve not only the optical properties but also the external light efficiency of the organic light emitting device (OLED), development has focused on increasing the refractive index of a filler.

However, there is a problem that the epoxy initiator used in the composition based on the epoxy resin often contains a heavy metal, or has low selectivity for epoxy materials. Therefore, as for the filler containing the epoxy initiator, monomers and oligomers applicable for lowering the dielectric constant and increasing the refractive index are limited.

Thus, acrylate-based fillers have been developed, and azo-based and peroxide-based BPO (benzoyl peroxide) are most commonly used as thermal initiators of acrylates used in the heat curing system.

However, in the case of the azo-based and peroxide-based initiators, as N₂ and CO₂ gases are generated as reaction by-products, bubbles are generated inside when applied to a closed system, which leads to the problem of expansion of the material and separation (detachment) of the upper and lower substrates bonded together.

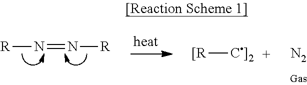

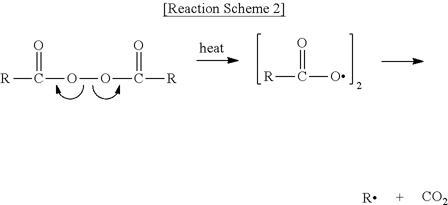

Reaction Scheme 1 shows the reaction by-product of the azo-based initiator, and Reaction Scheme 2 shows the reaction by-products of the peroxide-based initiator.

Therefore, there is a need to develop a new filler material for use in device encapsulation technology that can eliminate or minimize generation of bubbles inside after the initiation reaction.

### SUMMARY

It is an object of the present invention to provide a curable composition which is free from or can minimize the generation of bubbles inside due to by-products after the initiation reaction even when applied to a closed system, and thereby can prevent the problem of separation (detachment) of the upper and lower substrates bonded together.

It is another object of the present invention to provide a cured layer using the curable composition, and a device including the same.

Provided herein is a curable composition comprising:
a curable monomer;
a nitroxide-based initiator; and
a chain transfer agent containing an aromatic structure.

Also provided herein is a cured layer comprising a cured product of the above-mentioned curable composition.

Further provided herein is a device comprising the above-mentioned cured layer.

According to the present invention, as a nitroxide-based initiator and a chain transfer agent are used in combination, the generation of bubbles may be eliminated or minimized after the initiation reaction when applied to a closed system that seals a device, thereby being able to prevent expansion of the material and provide a cured product having a uniform shape.

Therefore, the present invention prevents the problem of separation (detachment) of the bonded upper and lower substrates of the device, and improves the sealing property of the device, thereby preventing oxygen and moisture from flowing in from the outside and improving the performance of the device.

### BRIEF DESCRIPTION OF THE DRAWING

FIG. 1 shows a cross-sectional structure of encapsulation between upper and lower substrates in an organic light emitting device.

FIG. 2 schematically illustrates manufacturing process of the specimen for measuring the presence or absence of generation of bubbles and the curability of Examples and Comparative Examples.

FIG. 3 shows the result of observing and comparing the presence or absence of generation of bubbles in Example 3 and Comparative Examples 1 and 2.

FIG. 4 shows the results of comparing the size and number of bubbles generated during curing through FIB-SEM measurement for Example 3 and Comparative Examples 1 and 2.

### DETAILED DESCRIPTION

The present invention will be described in more detail below. Terms or words used in the present specification and claims should not be construed as limited to ordinary or dictionary terms, and the present invention should be construed with meanings and concepts that are consistent with the technical idea of the present invention based on the principle that the inventors may appropriately define concepts of the terms to appropriately describe their own invention in the best way.

The terms “comprise,” “include”, “have”, etc. are used herein to specify the presence of stated feature, region, integer, step, action, element and/or component, but do not preclude the presence or addition of other feature, region, integer, step, action, element and/or component.

The term “(meth)acrylate” as used herein includes both acrylate and methacrylate.

Now, a curable composition, a cured layer comprising a cured product thereof, and a device comprising the cured layer according to specific embodiments of the present invention will be described in more detail.

According to an embodiment of the present invention, there can be provided a curable composition comprising: a curable monomer; a nitroxide-based initiator; and a chain transfer agent containing an aromatic structure.

The present invention relates to a curable composition for use as a filler for encapsulating devices.

The curable composition of one embodiment employs a nitroxide-based initiator capable of forming stable free radicals, and thereby minimizes the generation of reaction by-products and allows initiation of the curable monomer, namely, the (meth)acrylate monomer, which has been free from or minimized the generation of bubbles.

Further, the curable composition can improve the curability of the curable monomer by using a chain transfer agent together with a nitroxide-based initiator.

Therefore, if the curable composition of the present invention is used, it can eliminate or minimize the generation of bubbles when applied to a closed system (e.g., sealed environment) for encapsulating devices, which can thus prevent expansion of the material and provide a cured product having a uniform shape to thereby prevent the problem of separation (detachment) of the upper and lower substrates bonded together.

Specifically, less than 5/mm², for example less than 1/mm² of bubbles having a diameter of 0.05 μm to 1000 μm may exist in the cured product of the curable composition. If the diameter of bubbles in the cured product is 1000 μm or more, a non-uniform cured product may be formed, and separation between the upper and lower substrates may occur.

As the curable monomer used in the curable composition of the present invention, various well-known monomers or oligomers capable of improving the refractive index and optical properties can be applied, and the type thereof is not limited.

For example, the curable monomer may include one or more (meth)acrylate-based monomers.

The (meth)acrylate-based monomer may be a multifunctional (meth)acrylate monomer having at least one photocurable functional group having a double bond.

As the curable monomer, at least one selected from the group consisting of polyethylene glycol diacrylate, O-Phenylphenol EO acrylate, 2-(2-biphenyloxy)ethyl acrylate, ethoxylated bisphenol fluorine diacrylate, benzyl acrylate, 3-hydroxy-2,2-dimethylpropyl 3-hydroxy-2,2-dimethylpropionate diacrylate, 2-(2-biphenyloxy)ethyl acrylate, hexyl acrylate, 1,6-heaxnediol diacrylate, pentaerythritol triacrylate, bisphenol fluorene diacrylate, di(ethylene glycol)diacrylate, hexanediol diacrylate, di(trimethylolpropane)tetraacrylate, trimethylolpropane triacrylate, isobonyl acylate, 1,6-hexanediol diacrylate, 1,12-dodecanediol dimethacrylate, benzyl methacrylate, isodecyl methacrylate, dicyclopentanyl methacrylate and cyclohexyl methacrylate can be used.

In one example, the curable monomer may be a mixture of one or more, two or more, three or more, four or more, or five or more selected from the group consisting of polyethylene glycol diacrylate, O-Phenylphenol EO acrylate, 2-(2-biphenyloxy)ethyl acrylate, ethoxylated bisphenol fluorine diacrylate, benzyl acrylate, 3-hydroxy-2,2-dimethylpropyl 3-hydroxy-2,2-dimethylpropionate diacrylate, 2-(2-biphenyloxy)ethyl acrylate, hexyl acrylate, 1,6-heaxnediol diacrylate, pentaerythritol triacrylate, bisphenol fluorene diacrylate, di(ethylene glycol)diacrylate, hexanediol diacrylate, di(trimethylolpropane)tetraacrylate, trimethylolpropane triacrylate, isobonyl acylate, 1,6-hexanediol diacrylate, 1,12-dodecanediol dimethacrylate, benzyl methacrylate, isodecyl methacrylate, dicyclopentanyl methacrylate and cyclohexyl methacrylate. Moreover, when the curable monomer is a mixture, the mixing ratio thereof is not particularly limited, and they can be appropriately mixed for use as necessary.

The curable monomer may be included in an amount of 84 to 97% by weight with respect to the total curable composition. If the content of the curable monomer is 84% by weight or less, there is a problem that the curing rate is low, and if the content is 97% by weight or more, there is a problem that the curing reaction does not occur.

The nitroxide-based initiator has stable free radicals, which can thus allow initiation of (meth)acrylate-based monomers without reaction by-products, and therefore, can eliminate or minimize the generation of bubbles, unlike the prior art, after the initiation reaction.

The nitroxide-based initiator according to an embodiment of the invention may include a cyclic nitroxide compound or a linear nitroxide compound, and the cyclic nitroxide compound may include at least one ring structure among alicyclic or aromatic ring structures.

In one example, the cyclic nitroxide-based initiator may be a nitroxide compound including a heterocyclic structure containing a nitrogen (N) atom, and the nitroxide compound having a heterocyclic structure may be a cyclic compound containing N of the following Chemical Formula 1.

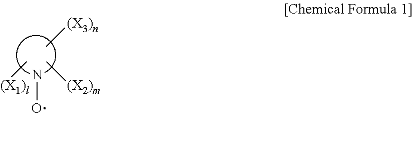

In Chemical Formula 1,
the ring structure contains 2 to 7 carbons,
each of the X₁ to X₃ independently includes hydrogen, an alkyl group, an aryl group, an amide group, an amine group, a (meth)acrylate group, a carbonyl group, a carboxyl group, an epoxy group, an ether group, an oxo group, or a hydroxy group,
each of the 1, m, and n is independently an integer of 0 to 2, and
any one or more of the X₁ to X₃ may have a fused structure fused with a ring structure containing nitrogen (N).

The ring structure of Chemical Formula 1 may contain a double bond. One or more positions of the ring structure may be substituted with oxygen, nitrogen, or sulfur.

The cyclic nitroxide-based initiator of Chemical Formula 1 may be a cyclic compound containing N of the following Chemical Formula 1-1.

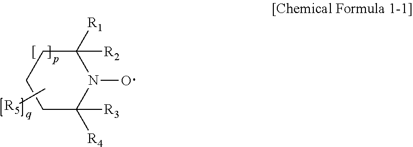

In Chemical Formula 1-1,
each of the R₁ to R₄ is independently hydrogen or an alkyl group,
each R₅ is independently hydrogen, an alkyl group, an aryl group, an amide group, an amine group, a (meth)acrylate group, a carbonyl group, a carboxyl group, an epoxy group, an ether group, an oxo group or a hydroxy group,
the p is an integer of 0 to 3, and
q is an integer of 0 to 4, with the proviso that when q is 2 or more, adjacent R₅s can be bonded together to form a ring.

The nitroxide-based initiator, which is a cyclic nitroxide compound of Chemical Formula 1, may be any one selected from the following structural formulas.

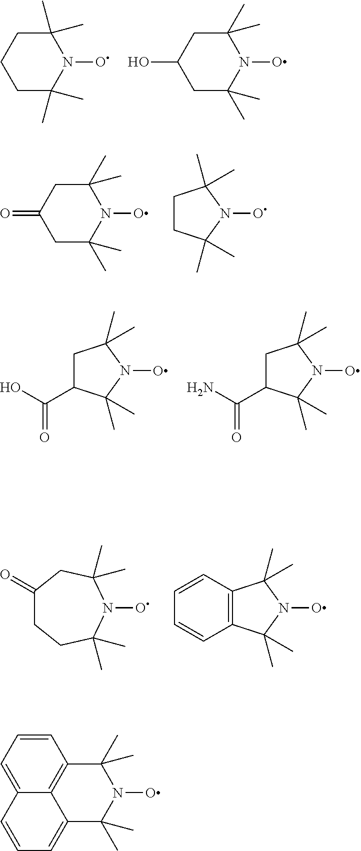

In the illustrative examples of the compound of Chemical Formula 1, a cyclic compound having a fused structure in which a ring forms one or more fused rings is as follows.

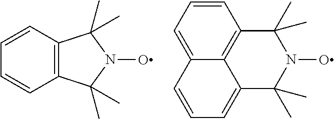

More specifically, Chemical Formula 1 may be TEMPO (2,2,6,6-tetramethylpiperidine-1-oxyl).

The linear nitroxide compound may be a linear structure compound containing N of the following Chemical Formula 2.

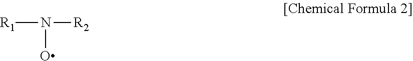

In Chemical Formula 2, R₁ and R₂ each independently represent a hydrocarbon group having 1 to 20 carbon atoms, and the R₁ and R₂ each independently include an alkyl group or a phenyl group.

In one example, the nitroxide-based initiator, which is a linear nitroxide compound of Chemical Formula 2, may be any one selected from the following structural formulas.

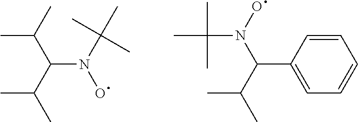

Further, the content of the nitroxide-based initiator may be 1% to 10% by weight, for example, 1% to 10% by weight, 1% to 8% by weight, or 1 to 4% by weight, with respect to the total curable composition.

If the content of the nitroxide-based initiator in the total composition is less than 1% by weight, the curing reaction may not occur, and if the content exceeds 10% by weight, the light transmittance may decrease.

Further, the present invention is characterized in that the above-mentioned nitroxide-based initiator and a chain transfer agent to be described below are used in combination, wherein the content of two components satisfies the range of the present invention, and the relative usage ratio between the two components is adjusted to a specific range for use.

In one example, the content ratio between the nitroxide-based initiator and the chain transfer agent may be 1:2 to 1:12, 1:2 to 1:10, or 1:3 to 1:8.

If the content ratio between the nitroxide-based initiator and the chain transfer agent is less than 1:2 and thus, a small amount of the chain transfer agent is used, it may be difficult to exhibit a sufficient curing reaction, and if the content ratio between the nitroxide-based initiator and the chain transfer agent exceeds 1:12 and thus, an excessive amount of the chain transfer agent is used, the curing rate may rather decrease.

Therefore, when using the nitroxide-based initiator and the chain transfer agent, the content ratio between the two components must be satisfied within the above range, thereby being able to excellently maintain transmittance, turbidity and optical properties at the same time while exhibiting an excellent curing rate of 90% or more.

Further, as the curable composition includes a chain transfer agent, the initiation efficiency of a specific initiator can be improved.

Specifically, hydrogen of the chain transfer agent is transferred to free radicals contained in the nitroxide-based initiator, and the chain transfer agent forms an anion and performs reaction with a (meth)acrylate. The nitroxide-based initiator must be used together with the chain transfer agent.

Such chain transfer agents include thiol-based compounds.

Moreover, among the thiol-based compounds, the chain transfer agent includes an aromatic thiol. The chain transfer agent includes one or more thiol groups, for example, one thiol group.

As the chain transfer agent includes an aromatic thiol, it has a lower pKₐ value than a thiol-based compound having an aliphatic substituent, and thus is more likely to emit a proton than an aliphatic thiol (pKₐ of aliphatic thiol: 9-10, pKₐ of aromatic thiol: 5-7).

Therefore, the aromatic thiol can contribute to increasing the reactivity of the curable monomer than the aliphatic thiol.

The reaction mechanism between the nitroxide-based initiator and the chain transfer agent is shown in the following Reaction Scheme 3, and initiation reactivity can be improved by using a thiol-based compound.

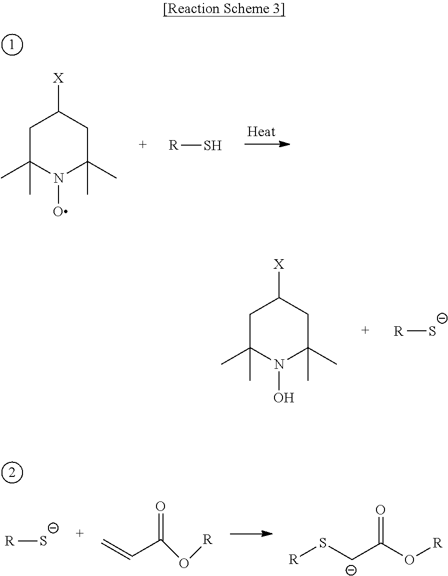

In Reaction Scheme 3, R is a C1-C18 alkyl group having a substituted or unsubstituted aryl group.

The chain transfer agent may be included in an amount of 2% to 15% by weight or 2 to 12% by weight, and more specifically 3 to 10% by weight with respect to the total curable composition. If the content of the chain transfer agent is less than 2% by weight, the curing reaction may not occur, and if the content is more than 15% by weight, the curing rate may be low.

The curable composition may be used for the purpose of a display.

Therefore, according to another embodiment of the present invention, there can be provided a cured layer comprising a cured product of the curable composition.

The cured product may include an olefin polymer which forms a crosslink by curing a (meth) acrylate-based monomer without a by-product by the initiation of the reaction of a nitroxide-based initiator and a chain transfer agent. The cured product may be a polymer having a high refractive index and a low dielectric constant in various forms depending on the type of (meth)acrylate-based monomer, and thus, its form is not particularly limited, and it may have various forms, such as a homo copolymer, a block copolymer, a random copolymer, or a graft copolymer, depending on the type of monomer and the mechanism of polymerization reaction described above.

Further, the cured layer including the cured product of the curable composition may have a refractive index of 1.5 or more based on a thickness of 10 μm.

Further, the dielectric constant of the cured layer including the cured product of the curable composition may be 3.5 or less based on a thickness of 10 μm.

Further, in contrast to the prior art, the cured layer does not use an azo-based or peroxide-based initiator, and thus, less than 5/mm², for example less than 1/mm² of bubbles having a diameter of 0.05 μm to 1000 μm may exist therein.

The filler of conventionally used display devices typically exhibit a refractive index of less than 1.5, and a part of the light emitted from the light emitting layer is totally reflected due to the difference in refractive index between the filler layer and the light emitting element, which causes a problem that external light efficiency decreases and power consumption increases.

On the other hand, the cured layer of the present invention can be utilized as a filler of a display device. Therefore, the refractive index of the filler layer can be increased to match the refractive index of the light emitting device, thereby increasing external light efficiency and reducing power consumption.

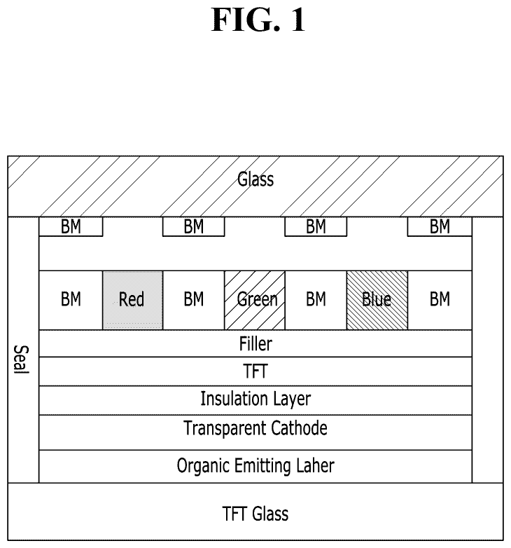

In one example, the present invention can be used as a filler in the display device shown in FIG. 1.

That is, in the display device, an outer sealant and an inner filler must be applied in order to block off external moisture and oxygen and extend the lifetime. When external moisture penetrates, the bubble formation and internal detachment due to the generation of hydrogen gas prevent the flow of current, which makes it difficult to generate light. Oxygen that flows in from the outside also finely oxidizes the internal electrodes, hindering the flow of current and attenuating the luminous effect. Therefore, in the present invention, by using the cured layer comprising the curable composition as an internal filler of the display device, it is possible to prevent external moisture from penetrating, facilitate the generation of light, maximize the luminous effect, and improve the efficiency of external light, thereby lowering power consumption compared to the prior art and improving the performance of the display device.

In addition, although there may be a problem of driving failure due to external static electricity in the light emitting device, the cured layer of the present invention can exhibit a low dielectric constant, thereby lowering the capacitance of the filler layer to solve the driving failure problem of the conventional case.

Further, according to the present invention, there can be provided a device comprising the cured layer.

The device to be encapsulated using the curable composition includes both an optical device and an optoelectronic device, and examples thereof are not limited. In one example, the device includes a solar cell, an optical semiconductor device, a light emitting device, an optical display device, and other optical devices, and may also include a gate electrode of an optical semiconductor or optical display device.

Since the method of applying the curable composition of the present invention to a display can be carried out by a conventional method well known in the art, detailed description thereof will be omitted.

### EXAMPLES

Hereinafter, the preferred examples are provided for better understanding the present invention. However, these examples are for illustrative purposes only, and the scope of the invention is not limited to or by them.

The (meth)acrylic-based compounds, initiators, and chain transfer agent components shown in Tables 1 to 3 below were prepared, and for convenience, each component was classified by a symbol. Then, the materials shown in Tables 1 to 3 were mixed at the composition and content shown in Table 4 below to prepare a curable composition.

TABLE 1

| | Curable monomer: (meth)acrylic-based compound |
|---|---|
| A | Polyethylene glycol Diacrylate |
| B | O-phenylphenol EO Acrylate |
| C | Mixture of the following five monomers:weight ratio |
| | 1. Ethoxylated bisphenol Fluorine diacrylate, 55 wt. % |
| | 2. Benzyl acrylate, 17 wt. % |
| | 3. 2-(2-Biphenyloxy)ethyl acrylate, 14 wt. % |
| | 3. O-phenylphenol EO Acrylate, 8 wt. % |
| | 4. Polyethylene glycol Diacrylate, 6 wt. % |
| D | Mixture of the following five monomers:weight ratio |
| | 1. Ethoxylated bisphenol Fluorine diacrylate, 35 wt. % |
| | 2. Dicyclopentanyl Methacrylate, 20 wt. % |
| | 3. 1,12-Dodecanediol Dimethacrylate, 17 wt. % |
| | 4. O-phenylphenol EO Acrylate, 15 wt. % |
| | 5. Isobornyl acrylate, 13 wt. % |

TABLE 2

| | | Initiator |
|---|---|---|
| D-1 | Initiator 1 | TEPMPO (2,2,6,6-Tetramethylpiperidine-1-oxyl) |
| | NO based | |
| D-2 | Initiator 1 | 4-Hydroxy-TEMPO |
| | NO based | |
| E | Initiator 2 | Benzoyl peroxide |
| | BPO based | |
| F | Initiator 3 | Dimethyl2,2 Azobis(2-methylpropinoate) |
| | Azo based | |

TABLE 3

| | Chain transfer agent: thiol-based compound |
|---|---|
| G | Triphenylmethane Thiol |
| H | 4-Methoxybenzenethiol |
| I | 2,4-Dimethylbenzenethiol |
| J | 1-Propanethiol |
| K | Butyl 3-mercaptopropionate |
| L | Pentaerythritol tetra[3-mercaptopropionate] |

TABLE 4

| | (Meth)acrylic- | | | | | | | | | |
|---|---|---|---|---|---|---|---|---|---|---|
| | based | | Initiator 1 | | Initiator 2 | | Initiator 3 | | Chain | |
| | compound | | (wt. %) | | (wt. %) | | (wt. %) | | transfer agent | |
| | (wt. %) | | NO based | | BPO based | | Azo based | | (wt. %) | |
| Example 1 | A | 95.0 | D-1 | 1.0 | | | | | G | 4.0 |
| Example 2 | B | 95.0 | D-1 | 1.0 | | | | | G | 4.0 |
| Example 3 | C | 95.0 | D-1 | 1.0 | | | | | G | 4.0 |
| Example 4 | D | 95.0 | D-1 | 1.0 | | | | | G | 4.0 |
| Comparative | C | 98.5 | D-1 | 1.0 | | | | | G | 0.5 |
| Reference | | | | | | | | | | |
| Example 1 | | | | | | | | | | |
| Comparative | C | 98.0 | D-1 | 1.0 | | | | | G | 1.0 |
| Reference | | | | | | | | | | |
| Example 2 | | | | | | | | | | |
| Example 5 | C | 97.0 | D-1 | 1.0 | | | | | G | 2.0 |
| Example 6 | C | 96.5 | D-1 | 1.0 | | | | | G | 2.5 |
| Example 7 | C | 91.0 | D-1 | 1.0 | | | | | G | 8.0 |
| Example 8 | C | 87.0 | D-1 | 1.0 | | | | | G | 12.0 |
| Comparative | C | 95.5 | D-1 | 0.5 | | | | | G | 4.0 |
| Reference | | | | | | | | | | |
| Example 3 | | | | | | | | | | |
| Example 9 | C | 94.0 | D-1 | 2.0 | | | | | G | 4.0 |
| Comparative | C | 92.0 | D-1 | 4.0 | | | | | G | 4.0 |
| Reference | | | | | | | | | | |
| Example 4 | | | | | | | | | | |
| Comparative | C | 88.0 | D-1 | 8.0 | | | | | G | 4.0 |
| Reference | | | | | | | | | | |
| Example 5 | | | | | | | | | | |
| Comparative | C | 84.0 | D-1 | 12.0 | | | | | G | 4.0 |
| Reference | | | | | | | | | | |
| Example 6 | | | | | | | | | | |
| Example 10 | C | 95.0 | D-2 | 1.0 | | | | | G | 4.0 |
| Example 11 | C | 92.0 | D-2 | 2.0 | | | | | G | 4.0 |
| Example 12 | C | 95.0 | D-2 | 1.0 | | | | | H | 4.0 |
| Example 13 | C | 92.0 | D-2 | 2.0 | | | | | H | 4.0 |
| Example 14 | C | 95.0 | D-2 | 1.0 | | | | | I | 4.0 |
| Example 15 | C | 92.0 | D-2 | 2.0 | | | | | I | 4.0 |
| Example 16 | C | 95.0 | D-1 | 1.0 | | | | | H | 4.0 |
| Example 17 | C | 92.0 | D-1 | 2.0 | | | | | H | 4.0 |
| Example 18 | C | 95.0 | D-1 | 1.0 | | | | | I | 4.0 |
| Example 19 | C | 92.0 | D-1 | 2.0 | | | | | I | 4.0 |
| Comparative | C | 96.0 | | | E | 4.0 | | | | |
| Example 1 | | | | | | | | | | |
| Comparative | C | 96.0 | | | | | F | 4.0 | | |
| Example 2 | | | | | | | | | | |
| Comparative | C | 95.0 | D-1 | 1.0 | | | | | J | 4.0 |
| Example 3 | | | | | | | | | | |
| Comparative | C | 95.0 | D-1 | 1.0 | | | | | K | 4.0 |
| Example 4 | | | | | | | | | | |
| Comparative | C | 95.0 | D-1 | 1.0 | | | | | L | 4.0 |
| Example 5 | | | | | | | | | | |

### Experimental Example

### Preparation of Specimen

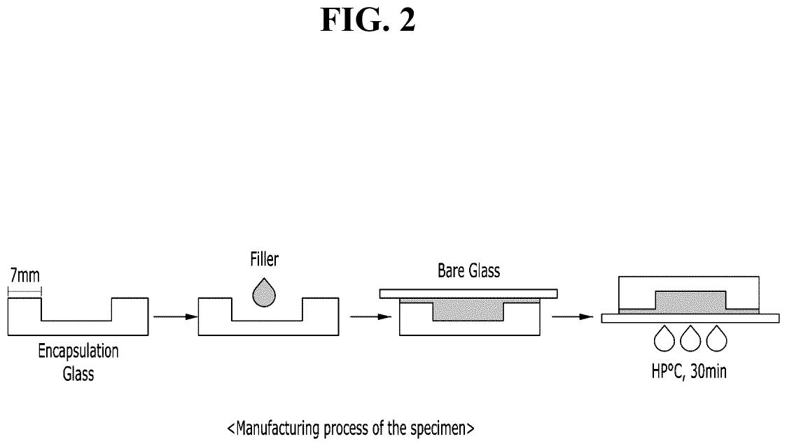

As shown in FIG. 2, 0.1-0.2 g of each curable composition was coated on a DAM-width 7 mm encapsulation glass so that there were no bubbles. Then, the top was covered with a bare glass with a 75×75 mm and 0.5T size so as not to generate bubbles.

Subsequently, heat curing was performed on a hot plate (HP) at 100° C. for 30 minutes to prepare a specimen. The presence or absence of bubbles and the curability of the specimen were confirmed.

### Judgment Criteria for Curability

∘: When the curing rate is more than 90%,

X: When the curing rate is less than 90%

### Experiment I. Presence or Absence of Bubbles

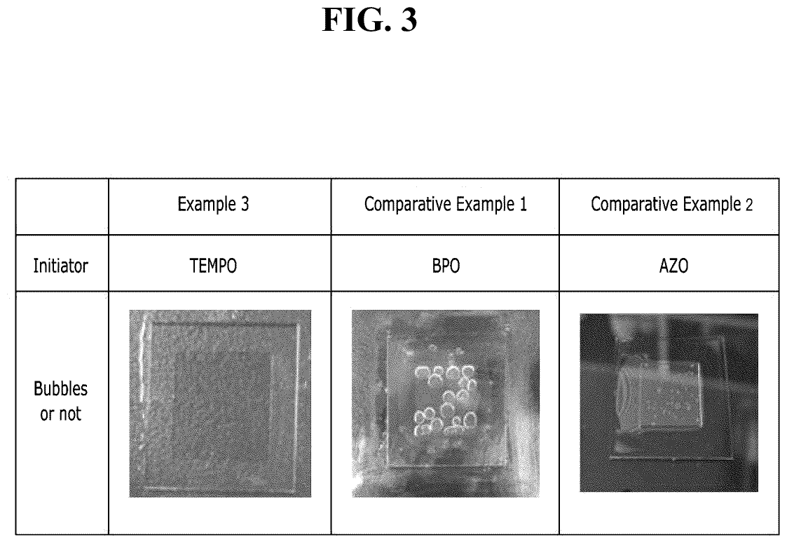

For Example 3 and Comparative Examples 1 and 2, whether bubbles were generated on the surface after heat curing was evaluated with the naked eyes, and the results are shown in FIG. 3.

Referring to FIG. 3, Example 3 of the present invention employed EPMPO as the nitroxide-based initiator, so that no bubbles were generated in the cured layer formed on the substrate.

On the other hand, in Comparative Examples 1 and 2, it appears that, considering that bubbles were generated in the cured layer formed on the substrate, CO₂ and N₂ were respectively generated inside the cured product by using conventional BPO and azo-based initiators.

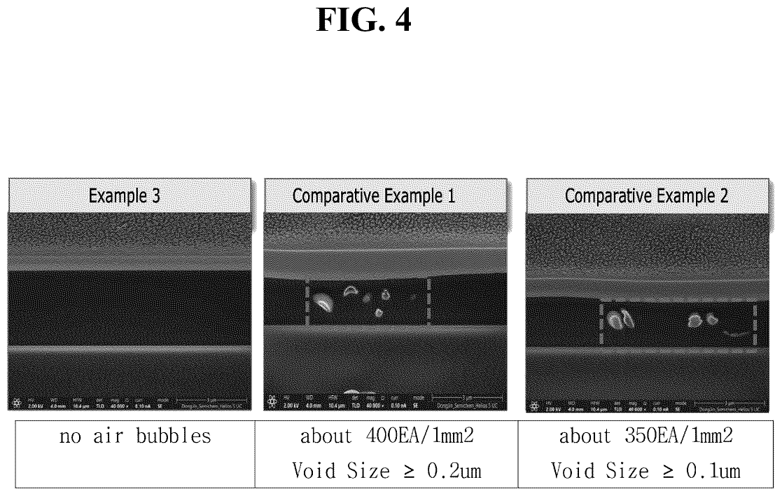

The size and number of bubbles generated during curing were confirmed through the following FIB-SEM measurement, and the results are shown in FIG. 4.

FIB (Focused Ion Beam) Condition: Hellos 5UC (Themofisher Scientific) Beam Current: 2.5 nA
1) The curable composition of Example 3, Comparative Example 1 and Comparative Example 2 was applied to a glass substrate.
2) After the Si-based release film was placed on the above 1), the film was heat-cured (100° C. for 30 minutes) to form a cured layer.
3) After forming the cured layer, the release film was removed, and a cross section of the cured layer was cut through FIB processing, and then the cross section was measured with an SEM to confirm the voids.

### Experiment II. Whether Curing is Possible Depending on the Type of (Meth)Acrylate Monomer

The occurrence of curing was confirmed for Examples 1 to 4 in which the type of (meth)acrylate monomer was different, and the results are shown in Table 5 below.

TABLE 5

| | Whether or not curing occurs |
|---|---|
| Example 1 | ◯ |
| Example 2 | ◯ |
| Example 3 | ◯ |
| Example 4 | ◯ |

Referring to Table 5, it was confirmed that by including the nitroxide-based initiator (TEPMPO) and the chain transfer agent, which is an aromatic thiol having a phenyl group, both aliphatic and aromatic (meth)acrylates can be cured regardless of the type of the (meth)acrylate-based monomer.

### Experiment III. Whether or not Curing is Possible Depending on the Type of Nitroxide-Based Initiator (TEMPO) and Chain Transfer Agent (Thiol)

The occurrence of curing was confirmed for Example 3, Examples 10 to 19, and Comparative Examples 3 to 5 depending on the type of the nitroxide-based initiator and chain transfer agent, and the results are shown in Table 6 below.

TABLE 6

| | Whether or not curing occurs |
|---|---|
| Example 3 | ◯ |
| Example 10 | ◯ |
| Example 11 | ◯ |
| Example 12 | ◯ |
| Example 13 | ◯ |
| Example 14 | ◯ |
| Example 15 | ◯ |
| Example 16 | ◯ |
| Example 17 | ◯ |
| Example 18 | ◯ |
| Example 19 | ◯ |
| Comparative Example 3 | X |
| Comparative Example 4 | X |
| Comparative Example 5 | X |

Referring to Table 6, when using not only TEMPO, which is a nitroxide initiator, but also other types of Hydroxy-TEMPO, Examples 3 and 10-19 using an aromatic thiol as a chain transfer agent exhibited better curability.

On the other hand, it was confirmed that Comparative Examples 3 to 5 using thiols containing no aromatic ring were not cured.

Therefore, it can be seen that depending on not only the type of initiator but also the thiol compound, which is a chain transfer agent, it has a great influence in determining whether or not curing occurs.

Thus, the curable composition must use a nitroxide-based initiator and an aromatic thiol in combination to thereby be excellent in curability and also prevent the generation of bubbles.

### Experiment IV. Curing Rate According to the Content of Aromatic Chain Transfer Agent (Thiol)

The curing rates of Example 3, Comparative Reference Examples 1 and 2, and Examples 5 to 8 were confirmed according to the content of the aromatic chain transfer agent, and the results are shown in Table 7 below.

Curing rate: The intensity of absorption peaks around 1635 cm⁻¹ (C═C) and 1720 cm⁻¹ (C═O) for the curable composition is measured by using FT-IR (NICOLET 4700). Then, the curing rate was calculated according to Equation 1 below.

[Equation 1]

Curing rate (%)=[1−(Y/Z)]×100 (1)

In Equation 1, Y is the ratio of the intensity of the absorption peak around 1635 cm⁻¹ (C═C) to the intensity of the absorption peak around 1720 cm⁻¹ (C═O) for the cured film, and Z is the ratio of the intensity of the absorption peak around 1635 cm⁻¹ (C═C) to the intensity of the absorption peak around 1720 cm⁻¹ (C═O) for the liquid phase of the curing composition.

TABLE 7

| | Curing rate (%) |
|---|---|
| Example 3 | 92.3 |
| Comparative Reference Example 1 | (44.7) |
| Comparative Reference Example 2 | (78.4) |
| Example 5 | 91.8 |
| Example 6 | 92.1 |
| Example 7 | 90.4 |
| Example 8 | 91.1 |

Referring to Table 7, Comparative Reference Examples 1 and 2 were not cured beyond the range of the chain transfer agent according to the present invention.

On the other hand, Example 3 and Examples 5 to 8 were cured with a curing rate of 90% or more. From these results, it was confirmed that the curing was achieved only when the content of the chain transfer agent relative to the initiator was at least 200% or more.

### Experiment V Optical Properties and Curing Rate According to the Content of Nitroxide-Based Initiator (TEMPO)

Optical properties and curing rates of Examples 3 and 9 and Comparative Reference Examples 3 to 6 were confirmed according to the content of the nitroxide-based initiator (TEMPO), and the results are shown in Table 8 below.
(1) Transmittance: A value measured in the wavelength range of 400 to 800 nm by UV/Vis Spectroscopy (CARY4000) for the curable composition.
(2) Turbidity, Yellowness, b*: measured with a Haze Meter (COH-400) for the curable composition.
(3) Curing rate: The intensity of absorption peaks around 1635 cm⁻¹ (C═C) and 1720 cm⁻¹ (C═O) for the curable composition is measured using FT-IR (NICOLET 4700). The curing rate was calculated according to Equation 1 below.

Curing rate (%)=[1−(Y/Z)]×100 [Equation 1]

In Equation 1, Y is the ratio of the intensity of the absorption peak around 1635 cm⁻¹ (C═C) to the intensity of the absorption peak around 1720 cm⁻¹ (C═O) for the cured film, and Z is the ratio of the intensity of the absorption peak around 1635 cm⁻¹ (C═C) to the intensity of the absorption peak around 1720 cm⁻¹ (C═O) for the liquid phase of the curing composition.

TABLE 8

| | Thick- | Trans- | | | | |
|---|---|---|---|---|---|---|
| | ness | mittance | | | Yellow- | Curing |
| | (μm) | (%) | Turbidity | b* | ness | rate (%) |
| Example 3 | 10 | 99.58 | 0.02 | 0.08 | 0.78 | 92.3 |
| Comparative | 10 | 99.63 | 0.03 | 0.06 | 0.24 | (22.4) |
| Reference | | | | | | |
| Example 3 | | | | | | |
| Example 9 | 10 | 99.36 | 0.04 | 0.23 | 1.46 | 91.8 |
| Comparative | 10 | 99.16 | 0.05 | 0.62 | 22.67 | (82.7) |
| Reference | | | | | | |
| Example 4 | | | | | | |
| Comparative | 10 | 92.35 | 4.08 | 2.48 | 54.48 | (64.2) |
| Reference | | | | | | |
| Example 5 | | | | | | |
| Comparative | 10 | 82.33 | 5.97 | 5.87 | 67.87 | (52.4) |
| Reference | | | | | | |
| Example 6 | | | | | | |

Looking at Table 8, Example 3 can ensure a transmittance of 99% or more and a haze of less than 0.1, b*, and has excellent optical properties.

At this time, Example 9 had slightly lowered optical properties than Example 3, but the content ratio between the nitroxide-based initiator and the chain transfer agent satisfied the range of 1:2 relative to the initiator, thereby exhibiting superior optical properties than those of Comparative Reference Examples 3 to 6. In addition, Example 9 exhibited excellent curing rate and turbidity properties.

On the other hand, as the content of the nitroxide-based initiator (TEMPO) increases as in Comparative Reference Examples 4 to 6, it showed a tendency for the optical properties to deteriorate. This is because the nitroxide-based initiator (TEMPO) itself has a red-based color.

Further, when the initiator content was less than 1 as in Comparative Reference Example 3, and when the chain transfer agent content did not satisfy the range of 1:2 to 1:12 relative to the initiator (Comparative Reference Examples 4 to 6), it showed a tendency for the curing rate to decrease relatively.

1. A curable composition comprising:
a curable monomer;
a nitroxide-based initiator; and
a chain transfer agent containing an aromatic structure.

2. The curable composition of claim 1, wherein the nitroxide-based initiator has a cyclic or linear structure.

3. The curable composition of claim 2, wherein the nitroxide-based initiator includes at least one ring structure among alicyclic or aromatic ring structures.

4. The curable composition of claim 2, wherein the nitroxide-based initiator includes a heterocyclic structure containing a nitrogen (N) atom.

5. The curable composition of claim 1, wherein the nitroxide-based initiator includes a nitro group having a free radical.

6. The curable composition of claim 1, wherein the nitroxide-based initiator includes a compound represented by Chemical Formula 1: 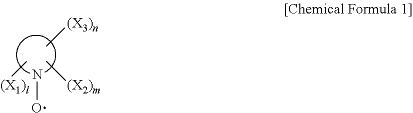
wherein, in Chemical Formula 1,
the ring structure contains 2 to 7 carbons,
the X₁ to X₃ each independently include, hydrogen, an alkyl group, an aryl group, an amide group, an amine group, a (meth)acrylate group, a carbonyl group, a carboxyl group, an epoxy group, an ether group, an oxo group, or a hydroxy group,
the l, m, and n are each independently an integer of 0 to 2, and
any one or more of the X₁ to X₃ have a fused structure that is fused with a ring structure containing nitrogen (N).

7. The curable composition of claim 6, wherein the ring structure contains a double bond, or
wherein one or more positions of the ring structure is substituted with oxygen, nitrogen, or sulfur.

8. The curable composition of claim 1, wherein the nitroxide-based initiator includes a compound represented by Chemical Formula 2: 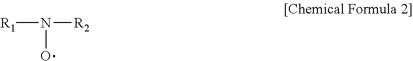
wherein, in Chemical Formula 2, R₁ and R₂ each independently represent a hydrocarbon group having 1 to 20 carbon atoms, and
the R₁ and R₂ each independently include an alkyl group or a phenyl group.

9. The curable composition of claim 8, wherein the nitroxide-based initiator is any one selected from the following structural formulas:

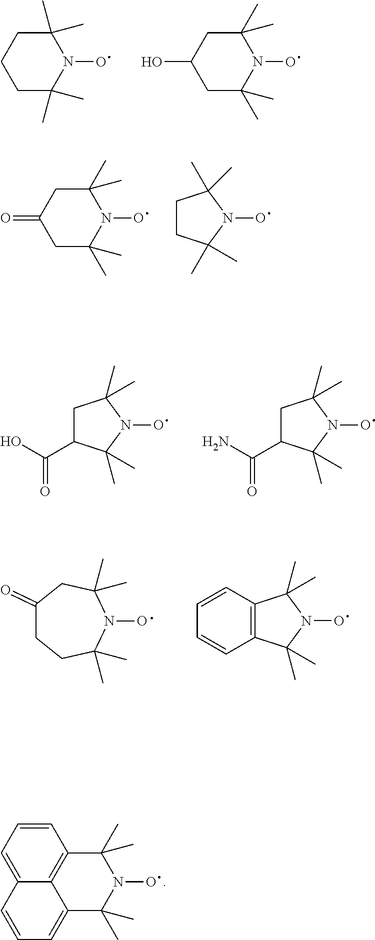

10. The curable composition of claim 8, wherein the nitroxide-based initiator is any one selected from the following structural formulas:

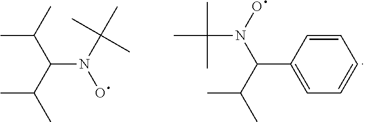

11. The curable composition of claim 1, wherein the chain transfer agent includes one or more thiol groups.

12. The curable composition of claim 1, wherein the chain transfer agent is included in an amount of 2% to 15% by weight with respect to the curable composition.

13. The curable composition of claim 1, wherein the nitroxide-based initiator is included in an amount of 1% to 10% by weight with respect to the total curable composition.

14. The curable composition of claim 1, wherein a content ratio between the nitroxide-based initiator and the chain transfer agent is 1:2 to 1:12.

15. The curable composition of claim 1, wherein the curable monomer includes (meth)acrylate-based monomer having one or more (meth)acrylate groups.

16. A cured layer comprising a cured product of the curable composition of claim 1.

17. The cured layer of claim 16, wherein the refractive index of the cured layer is 1.5 or more based on a thickness of 10 μm.

18. The cured layer of claim 16, wherein less than 5/mm² of bubbles having a diameter of 0.05 μm to 1000 μm exist in the cured layer.

19. A device comprising the cured layer of claim 16.

20. The device of claim 19, wherein the device is an organic light emitting diode (OLED) display device including the cured layer as an encapsulation layer.
